(19) United States
(12) Patent Application Publication
(10) Pub. No.: US 2023/0413646 A1
(43) Pub. Date: Dec. 21, 2023

(54) DISPLAY DEVICE

(71) Applicant: LG Display Co., Ltd., Seoul (KR)

(72) Inventors: Juyeon WON, Gimpo-si (KR); Jeongha SHIN, Seoul (KR); HyeongWook JANG, Goyang-si (KR)

(73) Assignee: LG Display Co., Ltd., Seoul (KR)

(21) Appl. No.: 18/200,867

(22) Filed: May 23, 2023

(30) Foreign Application Priority Data
May 24, 2022 (KR) 10-2022-0063267

(51) Int. Cl. H10K 59/80

(52) U.S. Cl. CPC H10K 59/8722

(57) ABSTRACT

A display device includes a substrate including an active area and a non-active area surrounding the active area, a sealing substrate disposed on the substrate, an adhesive film disposed between the substrate and the sealing substrate, a dam disposed between the substrate and the sealing substrate to surround the adhesive film and a lower alignment key disposed between the dam and the substrate to overlap the dam. Therefore, a non-active area can be reduced by removing the process tolerance on one side of the display device.

### CROSS-REFERENCE TO RELATED APPLICATIONS

This application claims the priority of Korean Patent Application No. 10-2022-0063267 filed on May 24, 2022, in the Korean Intellectual Property Office, the disclosure of which is incorporated herein by reference.

### BACKGROUND

### Technical Field

The present disclosure relates to a display device, and more particularly, to a display device having a reduced bezel area size.

### Discussion of the Related Art

Currently, with entering the full-fledged information era, the field of display devices that visually display electrical information signals is developing rapidly, and research is continuing to develop performance such as thin-thickness, light weight, and low power consumption for various display devices.

Representative display devices include liquid crystal display (LCD) device, electro wetting display (EWD) device and organic light emitting display (OLED) device.

On the other hand, in the display device, a minimum bezel area, i.e., a non-active area should be secured in order to secure reliability such as moisture permeation suppressing. However, since the non-active area is an area that does not display an image, there is a demand to increase the size of the active area and decrease the size of the non-active area to increase screen immersion and enhance aesthetic sense.

### SUMMARY

Accordingly, embodiments of the present disclosure are directed to a display device that substantially obviates one or more of the problems due to limitations and disadvantages of the related art.

An aspect of the present disclosure is to provide a display device having a reduced non-active area which is a bezel area.

Another aspect of the present disclosure is to provide a display device in which moisture permeation suppressing performance is not deteriorated even though the non-active area is reduced.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device comprises a substrate including an active area and a non-active area surrounding the active area, a sealing substrate disposed on the substrate, an adhesive film disposed between the substrate and the sealing substrate, a dam disposed between the substrate and the sealing substrate to surround the adhesive film and a lower alignment key disposed between the dam and the substrate to overlap the dam. Therefore, a process tolerance on one side of the display device can be removed.

Other detailed matters of the exemplary embodiments are included in the detailed description and the drawings.

According to the present disclosure, a dam and an alignment key for scribing are overlapped and disposed, and scribing is performed on the dam to remove a process tolerance on one side of the display device.

Therefore, according to the present disclosure, a non-active area can be reduced by removing the process tolerance on one side of the display device.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a plan view of a display device according to an exemplary embodiment of the present disclosure;

FIG. 2 is a cross-sectional view for a subpixel of the display device according to an exemplary embodiment of the present disclosure;

FIG. 3 is a cross-sectional view of the display device taken along a line III-III′ of FIG. 1;

FIG. 4 is a cross-sectional view of a display device according to another exemplary embodiment of the present disclosure;

FIG. 5 is a plan view for describing a method for manufacturing a display device according to an exemplary embodiment of the present disclosure; and

FIG. 6 is a cross-sectional view of the display device taken long a line VI-VI′ of FIG. 5.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

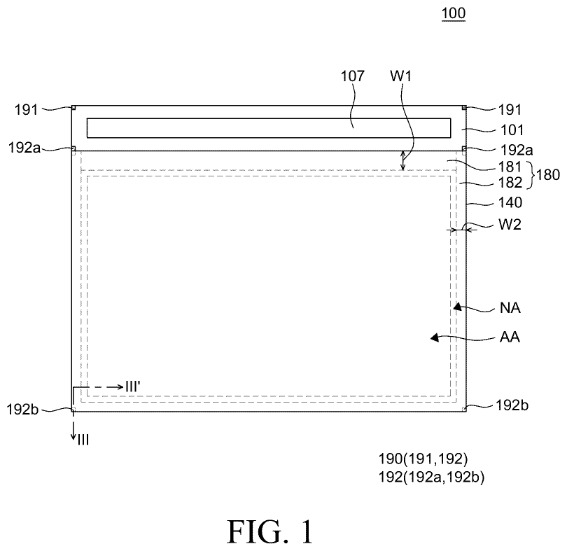

FIG. 1 is a plan view of a display device according to an exemplary embodiment of the present disclosure.

Referring to FIG. 1, the display device 100 according to an exemplary embodiment of the present disclosure may include a substrate 101, a sealing substrate 140, a pad part 107, an alignment key 190, and a dam 180.

The display device 100 is a device for displaying an image to a user.

In the display device 100, a display element for displaying the image, a driving element for driving the display element, wirings for transmitting various signals to the display element and the driving element, etc. may be disposed. The display element may be defined differently according to the type of display device 100, for example, if the display device 100 is an organic light emitting display device, the display element may be an organic light emitting element including an anode, an organic light emitting layer, and a cathode. For example, when the display device 100 is a liquid crystal display device, the display element may be a liquid crystal display element. Hereinafter, it is assumed that the display device 100 is the organic light emitting display device, but the display device 100 is not limited to the organic light emitting display device.

The display device 100 may include an active area AA and a non-active area NA.

The active area AA is an area in which the image is displayed in the display device 100.

A plurality of subpixels constituting a plurality of pixels and a circuit for driving the plurality of subpixels may be disposed in the active area AA. The plurality of subpixels is a minimum unit constituting the active area AA, and the display element may be disposed in each of the plurality of subpixels, and the plurality of subpixels may constitute the pixel. For example, the organic light emitting element including the anode, the organic light emitting layer, and the cathode may be disposed in each of the plurality of subpixels, but is not limited thereto. In addition, the circuit for driving the plurality of subpixels may include the driving element and the wirings. For example, the circuit may be constituted by a thin-film transistor, a storage capacitor, gate wirings, and data wirings, but is not limited thereto.

The non-active area NA is an area in which the image is not displayed.

Although it is illustrated that the non-active area NA surrounds the active area AA having a rectangular shape in FIG. 1, but shapes and layouts of the active area AA and the non-active area NA are not limited to an example illustrated in FIG. 1.

In other words, the active area AA and the non-active area NA may have shapes suitable for a design of an electronic device equipped with the display device 100. For example, an exemplary shape of the active area AA may be a pentagon, a hexagon, a circle, or an oval.

Various wirings and circuits for driving the organic light emitting element of the active area AA may be disposed in the non-active area NA. For example, the plurality of link wirings for transmitting signals to the plurality of subpixels and circuits of the active area AA, a driving IC such as a gate driver IC or a data driver IC, or the pad part 107 may be disposed in the non-active area NA, but is not limited thereto.

The display device 100 may include various additional elements for generating various signals or driving pixels in the active area AA. The additional elements for driving the pixels may include an inverter circuit, a multiplexer, or an electrostatic discharge (ESD) circuit. The display device 100 may also include an additional element associated with a function other than pixel driving. For example, the display device 100 may include additional elements that provide a touch sensing function, a user authentication function (e.g., fingerprint recognition), a multi-level pressure sensing function, and a tactile feedback function. The above-mentioned additional elements may be located in the non-active area NA and/or an external circuit connected to the connection interface.

The pad part 107 may be disposed to be applied with a signal from the outside. The pad part 107 is disposed in the non-active area NA of the display device 100 to be electrically connected to various wirings and circuits disposed in the active area AA, and a printed circuit board. For example, the pad part 107 may serve to transmit signals to gate wirings and data wirings, respectively, and may be constituted by a gate pad for transmitting a gate signal to the gate wirings and a data pad for transmitting a data signal to the data wirings, but is not limited thereto.

Meanwhile, in the display device 100 according to an exemplary embodiment of the present disclosure, the dam 180 may be provided in the non-active area NA in order to secure reliability of suppressing moisture permeation.

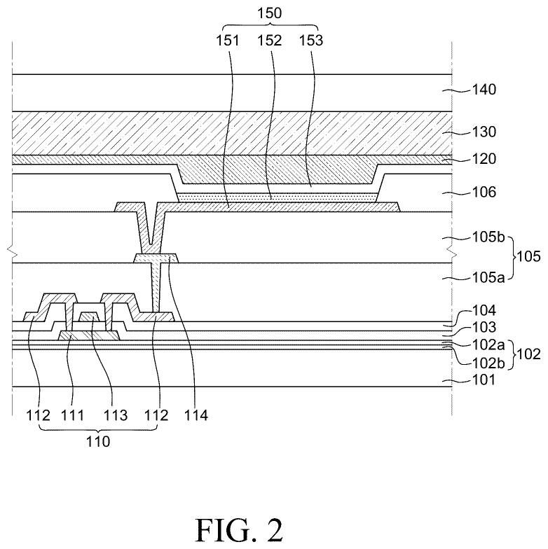

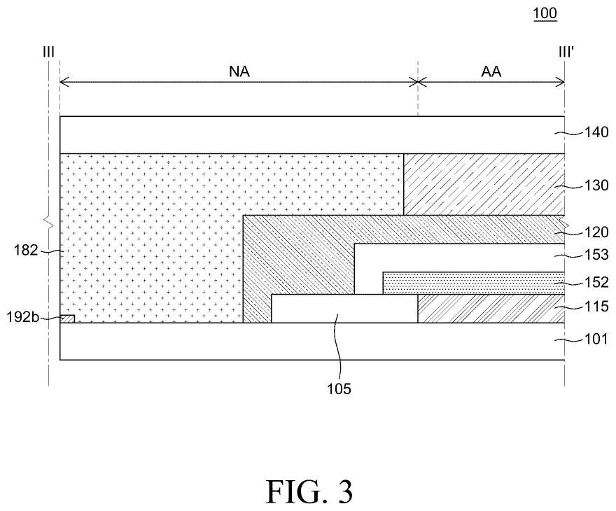

The dam 180 may include a first dam 181 disposed between the active area AA and the pad part 107, and a second dam 182 connected to one side and the other side of the first dam 181 to surround the active area AA. A more detailed description of the first dam 181 and the second dam 182 will be described in detail with reference to both FIGS. 2 and 3.

The alignment key 190 may be disposed on the substrate 101. The alignment key 190 may include a lower alignment key 192 and an additional alignment key 191.

The additional alignment key 191 may be disposed on the substrate 101. A bottom surface of the additional alignment key 191 may be disposed to be in contact with a top surface of the substrate 101. The additional alignment key 191 may be disposed in an area in which the sealing substrate 140 is not disposed, but is not limited thereto.

The lower alignment key 192 may be disposed between the substrate 101 and the dam 180. That is, the lower alignment key 192 may be disposed to overlap the dam 180. Specifically, the lower alignment key 192 may be disposed between the substrate 101 and the dam 180 to overlap the dam 180, and more specifically, disposed between the substrate 101 and the second dam 182 to overlap the second dam 182. A bottom surface of the lower alignment key 192 may be disposed to be in contact with a top surface of the substrate 101, and a top surface of the lower alignment key 192 may be disposed to be in contact with a bottom surface of the second dam 182. The lower alignment key 192 may include a first lower alignment key 192a and a second lower alignment key 192b.

A more detailed description of the lower alignment key 192 will be described in detail with reference to both FIGS. 2 and 3.

FIG. 2 is a cross-sectional view for a subpixel of the display device according to an exemplary embodiment of the present disclosure.

FIG. 3 is a cross-sectional view of the display device taken along the line III-III′ of FIG. 1.

In FIG. 3, for convenience of description, a pixel part 115 in the active area A is schematically illustrated. The pixel part 115 may include various components below an organic layer 152. In addition, the non-active area NA may also include various components, and is schematically illustrated for convenience of description.

Referring to FIGS. 2 and 3, in the display device 100 according to an exemplary embodiment of the present disclosure, a driving element 110 may be disposed on the substrate 101.

In addition, a planarization layer 105 may be disposed on the driving element 110.

In addition, the organic light emitting element 150 electrically connected to the driving element 110 is disposed on the planarization layer 105, and a passivation layer 120 is disposed on the organic light emitting element 150 to suppress oxygen and moisture from being penetrated.

An adhesive film 130 and a sealing substrate 140 may be sequentially disposed on the passivation layer 120. However, the display device 100 according to an exemplary embodiment of the present disclosure is not limited to such a lamination structure.

The substrate 101 may be a glass or plastic substrate. In the case of the plastic substrate, the plastic substrate adopts a polyimide or polycarbonate-based material to have a flexibility. In particular, polyimide may be applied to a high-temperature process, and since the polyimide is material, which is enabled to be coated, the polyimide is often used as the plastic substrate.

A buffer layer 102 may be disposed on the substrate 101.

The buffer layer 102 is a functional layer to protect various electrodes and the wirings from impurities such as an alkali ion which leaks from the substrate 101 or lower layers. The buffer layer 102 may have a multilayer structure constituted by a first buffer layer 102a and a second buffer layer 102b, but is not limited thereto. The buffer layer 102 may be composed of silicon oxide (SiOx), silicon nitride (SiNx), or multilayers thereof.

The buffer layer 102 may delay the spread of moisture and/or oxygen penetrated into the substrate 101. In addition, the buffer layer 102 may include a multi-buffer and/or an active buffer. The active buffer protects an active layer 111 composed of a semiconductor of the driving element 110, and may perform a function of interrupting various types of defects introduced from the substrate 101. The active buffer may be made of amorphous silicon (a-Si), etc.

The driving element 110 may be a form in which the active layer 111, a gate insulating layer 103, a gate electrode 113, an interlayer insulating layer 104, a source electrode, and a drain electrode 112 may be sequentially disposed, and is electrically connected to the organic light emitting element 150 through a connection electrode 114 to transmit a current or a signal to the organic light emitting element 150.

The active layer 111 may be located on the buffer layer 102. The active layer 111 may be made of poly silicon (p-Si), and in this case, a predetermined area may also be doped with impurities. Further, the active layer 111 may be made of the amorphous silicon (a-Si) or made of an organic semiconductor material such as pentacene. In addition, the active layer 111 may be made of an oxide semiconductor.

The gate insulating layer 103 may be located on the active layer 111. The gate insulating layer 103 may be made of an insulating inorganic material such as silicon oxide (SiOx) or silicon nitride (SiNx), and besides, also made of an insulating organic material.

The gate electrode 113 may be located on the gate insulating layer 103. The gate electrode 113 may be made of various conductive materials, for example, magnesium (Mg), aluminum (Al), nickel (Ni), chromium (Cr), molybdenum (Mo), tungsten (W), and gold (Au), or an alloy thereof.

The interlayer insulating layer 104 may be located on the gate electrode 113. The gate insulating layer 104 may be made of an insulating inorganic material such as silicon oxide (SiOx) or silicon nitride (SiNx), and besides, also made of an insulating organic material.

A contact hole where source and drain areas are exposed may be formed by selective removal of the gate insulating layer 103 and the interlayer insulating layer 104. The source electrode and the drain electrode 112 may be formed on the interlayer insulating layer 104 in a single-layer or multilayer structure as a material for the electrode. As necessary, an additional passivation layer made of an inorganic insulating material may also be formed to cover the source electrode and the drain electrode 112.

The planarization layer 105 may be disposed on the driving element 110 configured as such.

The planarization layer 105 may have a multilayer structure constituted by at least two layers. That is, for example, referring to FIG. 2, the planarization layer 105 may include a first planarization layer 105a and a second planarization layer 105b. The first planarization layer 105a may be disposed to cover the driving element 110, but disposed so that a part of the source electrode and the drain electrode 112 of the driving element 110 is exposed.

The planarization layer 105 may be extended to the non-active area NA.

The planarization layer 105 may be an overcoat layer, but is not limited thereto.

The connection electrode 114 for electrically connecting the driving element 110 and the organic light emitting element 150 may be disposed on the first planarization layer 105a. Further, although not illustrated in FIG. 2, various metallic layers serving as an electric cable/electrode such as a data line, and signal wirings may also be disposed on the first planarization layer 105a.

In addition, the second planarization layer 105b may be disposed on the first planarization layer 105a and the connection electrode 114. The number of various signal wirings are increased as the display device 100 has a high resolution, so the planarization layer 105 according to an exemplary embodiment of the present disclosure is constituted by two layers. Therefore, it is difficult to dispose all wirings on one layer while securing a minimum interval, so an additional layer is formed. Due to the addition of the additional layer (i.e., the second planarization layer 105b), a margin is created in the wirings arrangement, so that the wirings/electrodes layout design may be easier. In addition, when a dielectric material is used as the planarization layer 105 constituted by multilayers, the planarization layer 105 may also be used for a purpose of forming a capacitance between the metallic layers.

The second planarization layer 105b may be formed so that a part of the connection electrode 114 is exposed, and the drain electrode 112 of the driving element 110 and the anode 151 of the organic light emitting element 150 may be electrically connected by the connection electrode 114.

The organic light emitting element 150 may be configured with the anode 151, a plurality of organic layers 152, and the cathode 153 sequentially disposed. That is, the organic light emitting element 150 may be constituted by the anode 151 formed on the planarization layer 105, the organic layer 152 formed on the anode 151, and the cathode 153 formed on the organic layer 152.

The display device 100 may be implemented in a top emission scheme or a bottom emission scheme. In the case of the top emission scheme, a reflective layer which is made of an opaque conductive material having high reflectance, for example, silver (Ag), aluminum (Al), gold (Au), molybdenum (Mo), tungsten (W), and chromium (Cr), or alloys thereof may be added to a lower portion of the anode 151. Accordingly, the light emitted from the organic layer 152 is reflected on the anode 151 and faces an upper direction, i.e., the cathode 153 direction at an upper portion. On the contrary, in the case of the bottom emission scheme, the anode 151 may be made of only a transparent conductive material such as indium tin oxide (ITO), indium zinc oxide (IZO), and indium gallium zinc oxide (IGZO). Hereinafter, it will be assumed and described that the display device 100 of the present disclosure is the top emission scheme. However, the present disclosure is not limited thereto.

A bank 106 may be formed in a remaining area other than a light emitting area on the planarization layer 105. That is, the bank 106 has a bank hole for exposing the anode 151 corresponding to the light emitting area. The bank 106 may be made of an inorganic insulating material such as silicon nitride (SiNx) or silicon oxide (SiOx), or an organic insulating material such as BCB, an acrylic resin, or imide-based resin.

The bank 106 may be extended to the non-active area NA.

The organic layer 152 may be disposed on the anode 151 exposed by the bank 106. The organic layer 152 may include a light emitting layer, an electron injection layer, an electron transport layer, a hole transport layer, and a hole injection layer.

The organic layer 152 may be extended to the non-active area NA.

The organic layer 152 may be disposed on the planarization layer 105 in the non-active area NA.

The cathode 153 may be disposed on the organic layer 152.

In the case of the top emission scheme, the cathode 153 may include the transparent conductive material. For example, the cathode 153 may be made of indium tin oxide (ITO), indium zinc oxide (IZO), and indium gallium zinc oxide (IGZO). In the case of the bottom emission scheme, the cathode 153 may include any one of a metallic material such as gold (Au), silver (Ag), aluminum (Al), molybdenum (Mo), magnesium (Mg), palladium (Pd), and copper (Cu), or a group constituted by alloys thereof. Alternatively, the cathode 153 may be configured by laminating a layer made of the transparent conductive material such as tin oxide (ITO), indium zinc oxide (IZO), and indium gallium zinc oxide (IGZO), and the layer made of the metallic material such as gold (Au), silver (Ag), aluminum (Al), molybdenum (Mo), magnesium (Mg), palladium (Pd), and copper (Cu), or the alloys thereof, and is not limited thereto.

The cathode 153 may be extended to the non-active area NA.

The cathode 153 may be disposed to cover the organic layer 152 in the non-active area NA.

In the non-active area NA, the organic layer 152 may be disposed to be spaced from an end of the cathode 153 by a predetermined distance, but is not limited thereto.

In the non-active area NA, the cathode 153 may be disposed to be spaced from the end of the planarization layer 105 by a predetermined distance, but is not limited thereto.

The passivation layer 120 may be disposed on the cathode 153.

Meanwhile, although not illustrated, a capping layer may also be disposed on the organic light emitting element 150. The capping layer may be made of a material with a high refractive index and a high light absorption rate in order to reduce diffused reflection of external light.

In the non-active area NA, the passivation layer 120 may be an inorganic layer, and in this case, may be made of silicon oxide (SiOx), silicon nitride (SiNx), or multilayers thereof.

The passivation layer 120 may be extended to the non-active area NA.

The passivation layer 120 may be disposed to cover the cathode 153 and the planarization layer 105.

The adhesive film 130 and the sealing substrate 140 may be disposed on the passivation layer 120.

The adhesive film 130 may be disposed to cover the passivation layer 120.

The adhesive film 130 may protect the organic light emitting element 150 of the pixel part 115 from external moisture, oxygen, shock, etc., jointly with the passivation layer 120 and the sealing substrate 140. The adhesive film 130 may further include an absorbent. The absorbent may be a particle having hygroscopicity, and absorb moisture and oxygen from the outside to minimize moisture and oxygen from being penetrated into the pixel part 115. However, the present disclosure is not limited thereto.

The adhesive film 130 may include a filler.

The filler may be formed by using a transparent material so that luminance is not deteriorated in a process of transmitting light emitted by the organic light emitting element 150 into the sealing substrate 140. For example, the filler may also be configured with epoxy or olefin, or may also include talc, calcium oxide (CAO), barium oxide (BAO), zeolite, or silicon oxide (SiO).

The sealing substrate 140 may be disposed on the adhesive film 130.

The sealing substrate 140 may protect the organic light emitting element 150 of the pixel part 115 jointly with the adhesive film 130. The sealing substrate 140 may protect the organic light emitting element 150 from the external moisture, oxygen, shock, etc. The sealing substrate 140 may be disposed on the top of the substrate 101 so that the pad part 107 disposed on one side of the substrate 101 is exposed.

The dam 180 is disposed between the substrate 101 and the sealing substrate 140 at the edge of the substrate 101 to reinforce an adhesive force between the substrate 101 and the sealing substrate 140, and block the moisture.

Referring to FIGS. 1 and 3 together, the dam 180 may be disposed in the non-active area NA outside the active area AA. That is, the dam 180 may be formed to surround the pixel part 115 and the adhesive film 130 on a plane view, and bond and seal the substrate 101 and the sealing substrate 140 jointly with the adhesive film 130. Therefore, the dam 180 may be disposed in an area where the substrate 101 and the sealing substrate 140 are overlapped.

A side surface of the dam 180 may be disposed on the same plane with side surfaces of the substrate 101 and the sealing substrate 140. That is, the side surface of each of the substrate 101, the sealing substrate 140, and the dam 180 may be disposed on the same plane by the same process, i.e., a scribing process. For example, in a process of scribing a mother substrate into the unit of the display device 100, the mother substrate disposed on an outside of the display device 100 and a part of a component disposed on the mother substrate may be removed, and as a result, the side surface of the dam 180 may be disposed on the same plane with the side surfaces of the substrate 101 and the sealing substrate 140.

The dam 180 may include a first dam 181 and a second dam 182.

The first dam 181 may be disposed between the active area AA and the pad part 107. For example, the first dam 181 may be disposed on an upper periphery of the sealing substrate 140 disposed to expose the pad part 107. That is, the first dam 181 may be disposed to be adjacent to one side of four sides of the display device 100.

The second dam 182 may be disposed to be connected to one side and the other side of the first dam 181 to surround the active area AA. For example, the second dam 182 may be disposed along lower, and left and right peripheries of the display device 100. That is, the second dam 182 may be disposed to be adjacent to three sides of four sides of the display device 100.

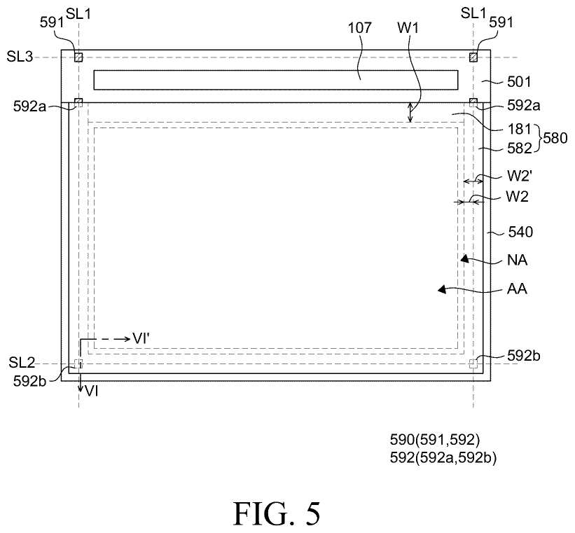

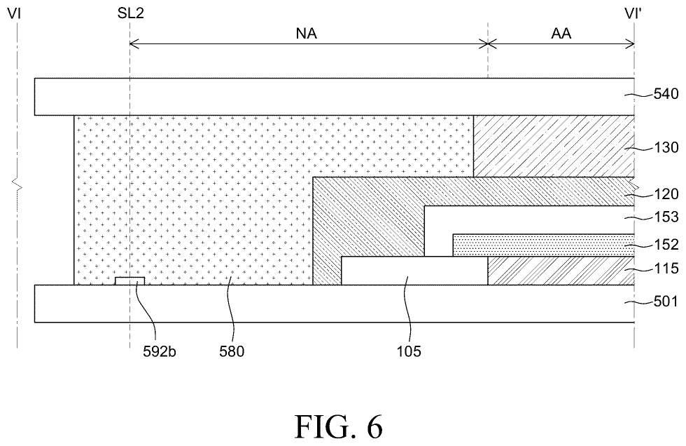

A width W1 of the first dam 181 may be different from a width W2 of the second dam 182. Specifically, the width W2 of the second dam 182 may be smaller than the width W1 of the first dam 181. In a manufacturing process of the display device 100, the widths of the first dam and the second dam are initially equal to each other, and then in the scribing process, a part of the second dam is removed, so the width of the second dam may be reduced. More detailed contents of the width W1 of the first dam 181 and the width W2 of the second dam 182 will be described below in detail with reference to FIGS. 5 and 6.

The alignment key 190 may be disposed in the non-active area NA on the substrate 101. The alignment key 190 is a key for accurately aligning the substrate 101 and the sealing substrate 140 in the scribing process. The alignment key 190 may be made of the same material as a conductive component formed on the top of the substrate 101. For example, the alignment key 190 may be made of the same material as components such as a thin-film transistor, a capacitor, or a wiring, but is not limited thereto. The alignment key 190 may be disposed on the periphery of the display device 100.

The alignment key 190 may include a lower alignment key 192 and an additional alignment key 191.

The lower alignment key 192 may be disposed between the substrate 101 and the dam 180. The lower alignment key 192 may be disposed to overlap the dam 180. Specifically, the lower alignment key 192 may be disposed between the substrate 101 and the second dam 182 to overlap the second dam 182. Therefore, a bottom surface of the lower alignment key 192 may be disposed to be in contact with a top surface of the substrate 101, and a top surface of the lower alignment key 192 may be disposed to be in contact with a bottom surface of the second dam 182. The lower alignment key 192 may be disposed on the periphery of the display device 100, and specifically, may be disposed to correspond to a corner of the sealing substrate 140.

A side surface of the lower alignment key 192 may be disposed on the same plane with the side surface of the dam 180. That is, the side surface of the lower alignment key 192 may be disposed on the same plane with the side surfaces of the substrate 101, the sealing substrate 140, and the second dam 182. In this case, the side surface of each of the substrate 101, the sealing substrate 140, the dam 180, and the lower alignment key 192 may be disposed on the same plane by the same process, i.e., the scribing process. For example, in the process of scribing the mother substrate into the unit of the display device 100, while components disposed in an area other than the display device 100 are removed, the side surfaces of each of the substrate 101, the sealing substrate 140, the dam 180, and the lower alignment key 192 may be disposed on the same plane. That is, in addition to the substrate 101, the sealing substrate 140, and the dam 180, the lower alignment key 192 may be exposed to the side surface of the display device 100. Here, what is meant by disposing on the same plane may mean that when two or more overlapped components are viewed from the top, side surfaces are scribed just right.

The lower alignment key 192 may include a first lower alignment key 192a and a second lower alignment key 192b.

The first lower alignment key 192a may be disposed in the non-active area NA between the active area AA and the pad part 107. Specifically, the first lower alignment key 192a may be disposed to correspond to an upper corner of the sealing substrate 140 adjacent to the pad part 107, and disposed on the periphery of the substrate 101. In this case, the first lower alignment key 192a may be constituted by a part which overlaps with the sealing substrate 140 and the other part which does not overlap with the sealing substrate 140.

In addition, the second lower alignment key 192b may be disposed in the non-active area NA outside the active area AA to which the pad part 107 is not adjacent. Specifically, the second lower alignment key 192b may be disposed to correspond to a lower corner of the sealing substrate 140 opposite to the pad part 107 not adjacent to the pad part 107 and a lower corner of the substrate 101. In this case, the entirety of the second lower alignment key 192b may overlap with the sealing substrate 140.

A size of the first lower alignment key 192a may be different from a size of the second lower alignment key 192b. The size of the second lower alignment key 192b may be smaller than the size of the first lower alignment key 192a. For example, through the scribing process conducted on the mother substrate, the scribing processes are conducted twice in the case of the second lower alignment key 192b, while the scribing process may be conducted once in the case of the first lower alignment key 192a. As such, in two scribing processes, the size of the second lower alignment key 192b may be reduced two times, while in one scribing process, the size of the first lower alignment key 192a may be reduced one times. Therefore, the size of the second lower alignment key 192b may be smaller than the size of the first lower alignment key 192a.

The additional alignment key 191 may be disposed to indicate a position for scribing by the unit of the display device 100 in the mother substrate. Therefore, the additional alignment key 191 may be disposed at the upper corner of the substrate 101 not overlapping the sealing substrate 140. For example, in a process of scribing a component disposed outside the display device 100 on the mother substrate, the additional alignment key 191 may be disposed on a top end of the display device 100, and disposed at the corner of the display device 100 through the scribing process. In this case, the side surface of the additional alignment key 191 may be disposed on the same plane with the side surface of the substrate 101, but is not limited thereto.

Meanwhile, in FIG. 1, it is illustrated that there are two additional alignment keys 191, and each of the first lower alignment key 192a and the second lower alignment key 192b is disposed in two, but the number of alignment keys 190 is not limited thereto.

When the organic layer of the organic light emitting element is exposed to the moisture or oxygen, characteristics of the organic layer are drastically deteriorated. Therefore, it is important to suppress the deterioration of the organic light emitting element from the permeation of the moisture and the oxygen by using a sealing technique of sealing the organic light emitting element from an external environment.

When the dam is used among various sealing techniques, the dam serves to block the moisture permeated on the side surface or delay the permeation of the moisture. In this case, a moisture permeation suppressing performance of the dam may be determined by the material constituting the dam and the width of the dam. However, since it is the material aspect that increases the moisture permeation suppressing performance of the material constituting the dam, it is difficult to improve in the display device manufacturing process. Therefore, it is important to increase the width of the dam in order to improve the moisture permeation suppressing performance of the dam in the display device manufacturing process. Therefore, there is a limitation in reducing the width of the dam in order to reduce the size of the non-active area. Further, the dam is generally manufactured by an application scheme through a dispenser process. However, since the dispenser process is a scheme of controlling an application amount by pneumatic pressure, it is difficult to precisely control the dispenser process, so a process margin should be surely considered.

On the other hand, in a manufacturing process of a current display device, the alignment key used for scribing in the mother substrate is disposed outside the dam. Therefore, a final display device in which the scribing process is completed, the alignment key and the substrate, and the sealing substrate remain on one side of the dam. Further, a significantly wide area remains by considering up to a process tolerance for the scribing process made on one side of the dam.

Therefore, in the display device 100 according to an exemplary embodiment of the present disclosure, it is characterized in that the dam 180, and the lower alignment key 192 for scribing are disposed to be overlapped, and scribing is conducted on the dam 180 to reduce the non-active area NA. Specifically, in a state in which the dam material is applied more widely than the width of the dam 180 required for moisture permeation suppressing, the dam 180 and the lower alignment key 192 are located to be overlapped. Thereafter, when the scribing process is conducted by using the lower alignment key 192 overlapped with the dam 180, the dam 180 and a part of the lower alignment key 192 are removed in the scribing process, and the side surface of the sealing substrate 140, the side surface of the lower alignment key 192, the side surface of the dam 180, and the side surface of the substrate 101 are disposed on the same plane. Therefore, in the display device 100 according to an exemplary embodiment of the present disclosure, since the sealing substrate, the substrate, and the lower alignment key disposed on the side of the dam 180 are removed, an area of an overall non-active area NA may be reduced by reducing the non-active area extended to the side of the dam 180.

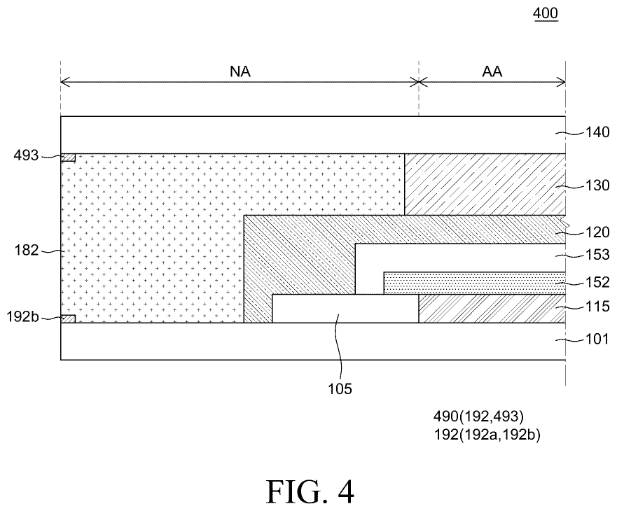

Further, in the display device 100 according to an exemplary embodiment of the present disclosure, a display device 100 in which the moisture permeation suppressing performance is not deteriorated may be provided even though the non-active area NA is reduced. As described above, the scribing process may be conducted by a scheme of leaving a width of the dam 180 required for the moisture permeation suppressing in a state of applying a dam material more widely than the width of the dam 180 required for the moisture permeation suppressing. Therefore, in the display device 100 according to an exemplary embodiment of the present disclosure, though the non-display area NA is reduced, the width of the dam 180 for maintaining the moisture permeation suppressing performance is maintained. Accordingly, reliability such as the moisture permeation suppressing may be secured. FIG. 4 is a cross-sectional view of a display device according to another exemplary embodiment of the present disclosure.

A display device 400 according to another exemplary embodiment of the present disclosure is different from the display device 100 according to an exemplary embodiment of the present disclosure of FIGS. 1 to 3 in terms of only a configuration of an alignment key 490, and other components are substantially the same, so a duplicated description is omitted. The same reference numeral will be used for the same component. Hereinafter, description of the same reference numeral may refer to FIGS. 1 to 3.

Referring to FIG. 4, the alignment key 490 may include the lower alignment key 192, an upper alignment key 493, and the additional alignment key 191.

Referring to FIG. 4, the upper alignment key 493 may be disposed between the dam 180 and the sealing substrate 140. The upper alignment key 493 may be disposed to overlap the dam 180. Specifically, the upper alignment key 493 may be disposed between the second dam 182 and the sealing substrate 140 to overlap the second dam 182. Therefore, a bottom surface of the upper alignment key 493 may be disposed to be in contact with the second dam 182, and a top surface of the upper alignment key 493 may be disposed to be in contact with the bottom surface of the sealing substrate 140. The upper alignment key 493 may be disposed on the periphery of the display device 100, and specifically, may be disposed to correspond to a corner of the sealing substrate 140. Meanwhile, the upper alignment key 493 may be disposed above the lower alignment key 192, and disposed to overlap the lower alignment key 192. For example, the upper alignment key 493 may be disposed at the same position as the lower alignment key 192 on the plane view.

A side surface of the upper alignment key 493 may be disposed on the same plane with the side surface of the dam 180. That is, the side surface of the upper alignment key 493 may be disposed on the same plane with the side surfaces of the substrate 101, the sealing substrate 140, and the second dam 182. In this case, the side surfaces of each of the substrate 101, the sealing substrate 140, the dam 180, the lower alignment key 192 and the upper alignment key 493 may be disposed on the same plane by the same process, i.e., the scribing process. For example, in the process of scribing the mother substrate into the unit of the display device 100, while components disposed in an area other than the display device 100 are removed, the side surfaces of each of the substrate 101, the sealing substrate 140, the dam 180, the lower alignment key 192 and the upper alignment key 493 may be disposed on the same plane. Here, what is meant by disposing on the same plane may mean that when two or more overlapped components are viewed from the top, side surfaces are just scribed.

Although not illustrated in FIG. 4, the upper alignment key 493 may include a first upper alignment key and a second upper alignment key.

The first upper alignment key may be disposed in the non-active area NA between the active area AA and the pad part 107. Specifically, the first upper alignment key may be disposed to correspond to an upper corner of the sealing substrate 140 adjacent to the pad part 107, and disposed on the periphery of the substrate 101. In this case, the first upper alignment key may be constituted by a part which is in contact with the sealing substrate 140 and the other part which is not in contact with the sealing substrate 140. In addition, the first upper alignment key may be disposed above the first lower alignment key 192a, and disposed to overlap the first lower alignment key 192a. For example, the first upper alignment key may be disposed at the same position with the first lower alignment key 192a on the plane view. The second upper alignment key may be disposed in the non-active area NA outside the active area AA to which the pad part 107 is not adjacent. Specifically, the second upper alignment key may be disposed to correspond to a lower corner of the sealing substrate 140 opposite to the pad part 107 not adjacent to the pad part 107 and a lower corner of the substrate 101. In this case, the entirety of the second upper alignment key may be in contact with the sealing substrate 140. In addition, the second upper alignment key may be disposed above the second lower alignment key 192b, and disposed to overlap the second lower alignment key 192b. For example, the second upper alignment key may be disposed at the same position with the second lower alignment key 192b on the plane view.

A size of the first upper alignment key may be different from a size of the second upper alignment key. The size of the second upper alignment key may be smaller than the size of the first upper alignment key. For example, through the scribing process conducted on the mother substrate, two scribing processes are conducted in the case of the second upper alignment key, while one scribing process may be conducted in the case of the first upper alignment key. As such, in two scribing processes, the size of the second upper alignment key may be reduced twice, while in one scribing process, the size of the first upper alignment key may be reduced once. Therefore, the size of the second upper alignment key may be smaller than the size of the first upper alignment key. In this case, the size of the first upper alignment key may be equal to the size of the first lower alignment key, and the size of the second upper alignment key may be equal to the size of the second lower alignment key. However, the present disclosure is not limited thereto.

As such, in the display device 400 according to another exemplary embodiment of the present disclosure, the dam 180, and the lower alignment key 192 and the upper alignment key 493 for scribing are disposed to be overlapped, and scribing is conducted on the dam 180. Therefore, the sealing substrate, the substrate, the lower alignment key, and the upper alignment key disposed on the side of the dam 180 are removed, so that the area of the overall non-active area NA may be reduced.

In addition, in the display device 400 according to another exemplary embodiment of the present disclosure, the scribing process may be conducted by a scheme of leaving the width of the dam 180 required for moisture permeation suppressing in a state of applying the dam material more widely than the width of the dam 180 required for the moisture permeation suppressing. Therefore, as the non-display are NA is reduced, but the width of the dam 180 for maintaining the moisture permeation suppressing performance is maintained. Accordingly, reliability such as the moisture permeation suppressing may be secured.

Meanwhile, when the moisture permeation suppressing performance of the dam 180 is enhanced, the dam 180 may be opaque. In addition, when a getter content of the dam 180 is enhanced, the dam 180 may be opaque. As such, when the dam 180 is made of an opaque material, if only one of the lower alignment key 192 and the upper alignment key 493 is used, the lower alignment key 192 or the upper alignment key 493 may not be visible in any one direction of the top or the bottom. Therefore, in the display device 400 according to another exemplary embodiment of the present disclosure, the upper alignment key 493 is additionally disposed between the dam 180 and the sealing substrate 140, which enables a scribing position to be accurately visible even when the dam 180 is made of the opaque material. Therefore, in the display device 400 according to another exemplary embodiment of the present disclosure, scribing may be easily and accurately conducted on the dam 180.

Meanwhile, for example, the dam 180 may be made of a material having a high modulus in order to easily remove the dam 180 upon scribing.

FIG. 5 is a plan view for describing a method for manufacturing a display device according to an exemplary embodiment of the present disclosure. FIG. 6 is a cross-sectional view of the display device taken long the line VI-VI′ of FIG. 5.

Referring to FIGS. 5 and 6, scribing lines SL1, SL2, and SL3 may be defined on a periphery of a mother substrate 501. The scribing lines SL1, SL2, and SL3 may be virtual lines for a guide upon manufacturing the display device 100 of an individual unit by scribing the mother substrate 501. As scribing is made along the scribing lines SL1, SL2, and SL3, the individual display device 100 may be manufactured.

The mother substrate 501, a mother sealing substrate 540, a dam 580, and an alignment key 590 may be disposed to be extended to the outside of the scribing lines SL1, SL2, and SL3.

The dam 580 may be disposed in the non-active area NA outside the active area AA in an area in which the mother substrate 501 and the mother sealing substrate 540 are overlapped. The dam 580 may be disposed to overlap the scribing lines SL1, SL2, and SL3 on the periphery of the display device 100.

A side surface of the dam 580 may be disposed on a different plane from side surfaces of the mother substrate 501 and the mother sealing substrate 540. That is, the side surfaces of the mother substrate 501 and the mother sealing substrate 540 may be disposed at the side of the dam 580. Specifically, on the plane view, the side surfaces of the mother substrate 501 and the mother sealing substrate 540 may be disposed to be extended to the outside of the side of the dam 580.

The dam 580 may include a first dam 181 and a second dam 582.

The first dam 181 may be disposed to be adjacent to one side of four sides of the display device 100 in the non-active area NA between the active area AA and the pad part 107.

The second dam 582 may be disposed to be connected to one side and the other side of the first dam 181 to surround the active area AA, and disposed to be adjacent to three sides of four sides of the display device 100.

The width W1 of the first dam 181 may be equal to a width W2′ of the second dam 582. The width W1 of the first dam 181 and the width W2′ of the second dam 582 may be set to be wider than the width of the dam required for moisture permeation suppressing by considering that the dam disposed outside the scribing lines SL1, SL2, and SL3 is removed.

The alignment key 590 may be disposed in the non-active area NA on the mother substrate 501. The alignment key 590 may be disposed to overlap the scribing lines SL1, SL2, and SL3 on the periphery of the display device 100.

The alignment key 590 may include a lower alignment key 592 and an additional alignment key 591.

The lower alignment key 592 may be disposed between the mother substrate 501 and the dam 580. The lower alignment key 592 may be disposed between the mother substrate 501 and the dam 580 to overlap the dam 580. Specifically, the lower alignment key 592 may be disposed at a position adjacent to the periphery of the display device 100 and the corner of the mother sealing substrate 540.

The side surface of the lower alignment key 592 may be disposed on a different plane from the side surface of the dam 580. That is, the side surface of the lower alignment key 592 may be disposed on a different plane from the side surfaces of the mother substrate 501, the mother sealing substrate 540, and the second dam 582. That is, the side surfaces of the mother substrate 501, the mother sealing substrate 540, and the second dam 582 may be disposed at the side of the lower alignment key 592. Specifically, on the plane view, the side surfaces of the mother substrate 501, the mother sealing substrate 540, and the second dam 582 may be disposed outside the side surface of the lower alignment key 592.

The lower alignment key 592 may include a first lower alignment key 592a and a second lower alignment key 592b.

The first lower alignment key 592a may be disposed in the non-active area NA between the active area AA and the pad part 107. Specifically, the first lower alignment key 592a may be disposed to correspond to an upper corner of the mother sealing substrate 540 adjacent to the pad part 107, and disposed at a position adjacent to the periphery of the mother substrate 501.

The second lower alignment key 592b may be disposed in the non-active area NA outside the active area AA to which the pad part 107 is not adjacent. Specifically, the second lower alignment key 592b may be disposed to correspond to a lower corner of the mother sealing substrate 540 opposite to the pad part 107 not adjacent to the pad part 107, and a lower corner of the mother substrate 501.

A size of the first lower alignment key 592a may be equal to a size of the second lower alignment key 592b.

The additional alignment key 591 may be disposed at the upper corner of the mother substrate 501, which does not overlap the mother sealing substrate 540. The additional alignment key 591 may have the same size as the first lower alignment key 592a and the second lower alignment key 592b.

The scribing lines SL1, SL2, and SL3 may be disposed at positions overlapping the alignment key 590. That is, the mother substrate 501, the mother sealing substrate 540, the dam 580, and the lower alignment key 592 may be disposed below the scribing lines SL1, SL2, and SL3. Therefore, in the final display device 100, the mother substrate 501, the mother sealing substrate 540, the dam 580, and the lower alignment key 592 disposed outside the scribing lines SL1, SL2, and SL3 may be partially removed, and as a result, the side surface of each of the substrate 101, the sealing substrate 140, the dam 180, and the lower alignment key 192 may be disposed on the same plane. Therefore, the non-active area NA may be reduced while passing through the scribing process.

Meanwhile, the positions of the scribing lines SL1, SL2, and SL3 may be determined by the width of the dam 180 required for moisture permeation suppressing. As the scribing process is conducted in the scribing lines SL1, SL2, and SL3, the width W2′ of the second dam 582 may be reduced. In this case, even though the width W2′ of the second dam 582 is reduced, there should be no problem in moisture permeation suppressing performance. Therefore, the width W2 of the second dam 182 in the final display device 100 should be configured to have a minimum width for moisture permeation suppressing. Therefore, the positions of the scribing lines SL1, SL2, and SL3 may be influenced by the width W2 of the second dam 182 in the final display device 100.

In the alignment key 590, an area disposed outside the scribing lines SL1, SL2, and SL3 may also be removed. Therefore, the size of the alignment key 590 may be reduced. For example, the first lower alignment key 592a is disposed at a position overlapped with a first scribing line SL1. Therefore, the size of the first lower alignment key 592a may be reduced. In addition, the second lower alignment key 592b is disposed at a position in which the first scribing line SL1 and the second scribing line SL2 are overlapped. Therefore, the size of the second lower alignment key 592b may be reduced.

In this case, a size of the second lower alignment key 592b cut twice by the first scribing line SL1 and the second scribing line SL2 may be reduced further than a size of the first lower alignment key 592a cut once by the first scribing line SL1.

Meanwhile, the additional alignment key 591 may be disposed at a position in which the first scribing line SL1 and a third scribing line SL3 are overlapped. Therefore, the additional alignment key 591 may be reduced to the same size as the second lower alignment key 592b by the first scribing line SL1 and the third scribing line SL3.

The exemplary embodiments of the present disclosure can also be described as follows:

According to an aspect of the present disclosure, there is provided a display device. The display device comprises a substrate including an active area and a non-active area surrounding the active area, a sealing substrate disposed on the substrate, an adhesive film disposed between the substrate and the sealing substrate, a dam disposed between the substrate and the sealing substrate to surround the adhesive film and a lower alignment key disposed between the dam and the substrate to overlap the dam.

A top surface of the lower alignment key may be in contact with a bottom surface of the dam, and a bottom surface of the lower alignment key may be in contact with a top surface of the substrate.

A side surface of the dam and a side surface of the lower alignment key may be disposed on the same plane.

A side surface of the substrate and a side surface of the sealing substrate may be disposed on the same plane with the side surface of the dam and the side surface of the lower alignment key.

The display device may further comprise an upper alignment key disposed between the dam and the sealing substrate to overlap the lower alignment key.

A top surface of the upper alignment key may be in contact with a bottom surface of the sealing substrate, and the bottom surface of the upper alignment key may be in contact with the top surface of the dam.

A side surface of the upper alignment key may be disposed on the same plane with a side surface of the substrate, the side surface of the sealing substrate, a side surface of the dam, and a side surface of the lower alignment key.

The display device may further comprise a pad part disposed on one side of the non-active area, wherein the dam may include a first dam disposed in the non-active area between the active area and the pad part, and a second dam connected to one side and the other side of the first dam and surrounding the active area.

A width of the second dam may be smaller than a width of the first dam.

A side surface of the second dam and a side surface of the lower alignment key may be disposed on the same plane.

The lower alignment key may be disposed to overlap the second dam.

The lower alignment key may include a first lower alignment key disposed in the non-active area between the active area and the pad part, and a second lower alignment key disposed in the non-active area outside the active area to which the pad part may be not adjacent.

A size of the first lower alignment key may be different from a size of the second lower alignment key.

The size of the second lower alignment key may be smaller than the size of the first lower alignment key.

The first lower alignment key may be constituted by a part which overlaps with the sealing substrate and the other part which does not overlap with the sealing substrate, and the entirety of the second lower alignment key may overlap with the sealing substrate.

A side surface of the lower alignment key may be exposed.

The lower alignment key may be disposed to correspond to a corner of the sealing substrate.

The display device may further comprise an additional alignment key disposed in an area of the substrate which does not overlap the sealing substrate.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device comprising:
a substrate including an active area and a non-active area surrounding the active area;
a sealing substrate disposed on the substrate;
an adhesive film disposed between the substrate and the sealing substrate;
a dam disposed between the substrate and the sealing substrate to surround the adhesive film; and
a lower alignment key disposed between the dam and the substrate to overlap the dam.

2. The display device according to claim 1, wherein a top surface of the lower alignment key is in contact with a bottom surface of the dam, and
a bottom surface of the lower alignment key is in contact with a top surface of the substrate.

3. The display device according to claim 1, wherein a side surface of the dam and a side surface of the lower alignment key are disposed on the same plane.

4. The display device according to claim 3, wherein a side surface of the substrate and a side surface of the sealing substrate are disposed on the same plane with the side surface of the dam and the side surface of the lower alignment key.

5. The display device according to claim 1, further comprising:
an upper alignment key disposed between the dam and the sealing substrate to overlap the lower alignment key.

6. The display device according to claim 5, wherein a top surface of the upper alignment key is in contact a the bottom surface of the sealing substrate, and
wherein a bottom surface of the upper alignment key is in contact with a top surface of the dam.

7. The display device according to claim 5, wherein a side surface of the upper alignment key is disposed on the same plane with a side surface of the substrate, a side surface of the sealing substrate, a side surface of the dam, and the side surface of the lower alignment key.

8. The display device according to claim 1, further comprising:
a pad part disposed on one side of the non-active area,
wherein the dam includes a first dam disposed in the non-active area between the active area and the pad part, and a second dam connected to one side and the other side of the first dam and surrounding the active area.

9. The display device according to claim 8, wherein a width of the second dam is smaller than a width of the first dam.

10. The display device according to claim 8, wherein the side surface of the second dam and a side surface of the lower alignment key are disposed on the same plane.

11. The display device according to claim 8, wherein the lower alignment key is disposed to overlap the second dam.

12. The display device according to claim 8, wherein the lower alignment key includes a first lower alignment key disposed in the non-active area between the active area and the pad part, and
a second lower alignment key disposed in the non-active area outside the active area to which the pad part is not adjacent.

13. The display device according to claim 12, wherein a size of the first lower alignment key is different from a size of the second lower alignment key.

14. The display device according to claim 13, wherein the size of the second lower alignment key is smaller than the size of the first lower alignment key.

15. The display device according to claim 12, wherein the first lower alignment key is constituted by a part which overlaps with the sealing substrate and the other part which does not overlap with the sealing substrate, and
wherein the entirety of the second lower alignment key overlaps with the sealing substrate.

16. The display device according to claim 1, wherein a side surface of the lower alignment key is exposed.

17. The display device according to claim 1, wherein the lower alignment key is disposed to correspond to a corner of the sealing substrate.

18. The display device according to claim 1, further comprising:
an additional alignment key disposed in an area of the substrate which does not overlap the sealing substrate.
